(19) United States
(12) Patent Application Publication
(10) Pub. No.: US 2008/0157240 A1
(43) Pub. Date: Jul. 3, 2008

(54) Seek-scan probe (SSP) memory including recess cavity to self-align magnets

(76) Inventor: Deguang Zhu, Fremont, CA (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/648,284

(22) Filed: Dec. 29, 2006

(51) Int. Cl. H01L 21/00

(52) U.S. Cl. 257/422; 438/88; 257/E29.167

(57) ABSTRACT

A seek-scan probe (SSP) memory including a recess cavity to self-align magnets includes a frame, a movable platform movably coupled to the frame, a coil coupled to the movable platform, and a cap wafer having coupled to the frame. The cap wafer includes a recess cavity to receive a magnet that produces a magnetic field. By energizing the coil while in the magnetic field a physical force is produced that is translated into movement of the movable platform.

### TECHNICAL FIELD

This disclosure relates generally to micro-electro-mechanical systems (MEMS), and in particular but not exclusively, relates to seek-scan probe (SSP) memories.

### BACKGROUND INFORMATION

Conventional solid state memories employ micro-electronic circuit elements for each memory bit. Since one or more electronic circuit elements are required for each memory bit (e.g., one to four transistors per bit), these devices can consume considerable chip “real estate” to store a bit of information, which limits the density of a memory chip. The primary memory element in these devices is typically a floating gate field effect transistor device that holds a charge on the gate of field effect transistor to store each memory bit. Typical memory applications include dynamic random access memory (DRAM), synchronous random access memory (SRAM), erasable programmable read only memory (EPROM), and electrically erasable programmable read only memory (EEPROM).

A different type of memory commonly known as a seek-scan probe (SSP) memory uses a non-volatile storage media as the data storage mechanism and offers significant advantages in both cost and performance over conventional memories based on charge storage. Typical SSP memories have storage media made of materials that can be electrically switched between two or more states having different electrical characteristics such as resistance or polarization dipole direction. One type of SSP memory, for example, uses a storage media made of a phase change material that can be electrically switched between a generally amorphous phase and a generally crystalline local order, or between different detectable phases of local order across the entire spectrum between completely amorphous and completely crystalline phases.

SSP memories are written to by passing an electric current through the storage media or applying an electric field to the storage media. Passing a current through the storage media is typically accomplished by passing a current between a sharp probe tip on one side of the storage media and an electrode on the other side of the media. In an idle state the probe tip is maintained at a certain distance above the storage media, but before the electric field or current can be applied to the storage media the probe tip must usually be brought close to, or in some cases in direct contact with, the storage media.

Current SSP memories address the media by using a movable tip platform to position hundreds to thousands of individual probe tips at particular locations with respect to the storage media. Other SSP memories may utilize a movable media platform to position the media at a particular location with respect to the tip platform rather than move the tip platform itself. Regardless, the movable platform is typically moved by way of an electromagnetic actuator by placing a coil on the movable platform and placing the magnet in a fixed location or vice versa. When a current is placed on the coil while in a magnetic field, forces such as a Lorentz force are translated into physical movement of the movable platform. By varying the current on the coil the position of the movable platform can be altered, thereby addressing various portions of the media.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIG. 1A is an exploded view of a seek-scan probe (SSP) memory, in accordance with an embodiment of the invention.

FIG. 1B is a sectional view of a SSP memory, in accordance with an embodiment of the invention.

FIG. 2A is a top view of a cap wafer with recess cavities, in accordance with an embodiment of the invention.

FIGS. 2B and 2C are sectional views of the cap wafer depicted in FIG. 2A, taken substantially along section lines 2B-2B and 2C-2C, respectfully.

FIG. 3A is a top view of an alternative cap wafer with recess cavities, in accordance with an embodiment of the invention.

FIGS. 3B and 3C are sectional views of the cap wafer depicted in FIG. 3A, taken substantially along section lines 3B-3B and 3C-3C, respectfully.

FIG. 4A is a top view of an alternative cap wafer with recess cavities, in accordance with an embodiment of the invention.

FIGS. 4B and 4C are sectional views of the cap wafer depicted in FIG. 4A, taken substantially along section lines 4B-4B and 4C-4C, respectfully.

FIG. 5A is a top view of an alternative cap wafer with recess cavities, in accordance with an embodiment of the invention.

FIGS. 5B and 5C are sectional views of the cap wafer depicted in FIG. 5A, taken substantially along section lines 5B-5B and 5C-5C, respectfully.

FIG. 6A is a top view of an alternative cap wafer with recess cavities, in accordance with an embodiment of the invention.

FIGS. 6B and 6C are sectional views of the cap wafer depicted in FIG. 6A, taken substantially along section lines 6B-6B and 6C-6C, respectfully.

FIG. 7A is a top view of an alternative cap wafer with recess cavities, in accordance with an embodiment of the invention.

FIGS. 7B and 7C are sectional views of the cap wafer depicted in FIG. 7A, taken substantially along section lines 7B-7B and 7C-7C, respectfully.

FIG. 8A is a top view of an alternative cap wafer with recess cavities, in accordance with an embodiment of the invention.

FIGS. 8B and 8C are sectional views of the cap wafer depicted in FIG. 8A, taken substantially along section lines 8B-8B and 8C-8C, respectfully.

FIG. 9A is a top view of an alternative cap wafer with recess cavities, in accordance with an embodiment of the invention.

FIGS. 9B and 9C are sectional views of the cap wafer depicted in FIG. 9A, taken substantially along section lines 9B-9B and 9C-9C, respectfully.

FIG. 10A is a top plain view of a magnet assembly, in accordance with an embodiment of the invention.

FIG. 10B is a side view of the magnet assembly depicted in FIG. 10A.

FIG. 10C is a top plain view of an alternative magnet assembly, in accordance with an embodiment of the invention.

FIG. 10D is a side view of the magnet assembly depicted in FIG. 10C.

FIG. 11 is a top plan view of a frame with a movable platform, in accordance with an embodiment of the invention.

FIG. 12 is a block diagram illustrating a demonstrative processing system, in accordance with an embodiment of the invention.

### DETAILED DESCRIPTION

Embodiments of a seek-scan probe (SSP) memory including a recess cavity to self-align magnets are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

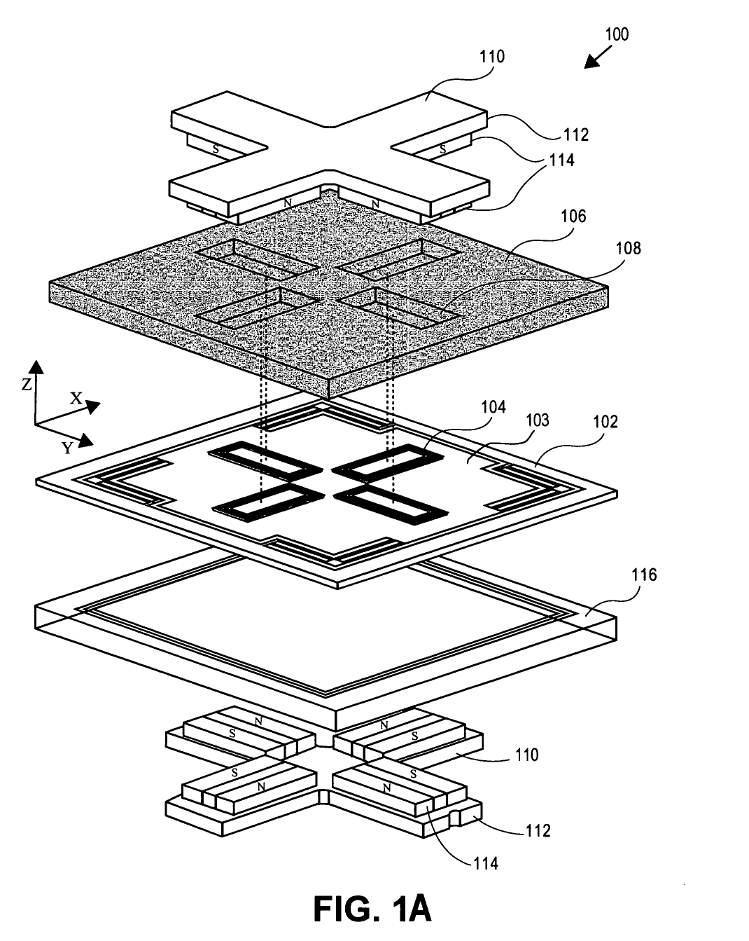

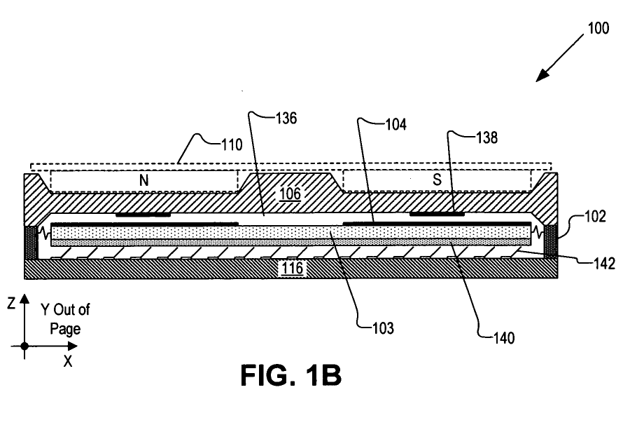

FIG. 1A is an exploded view of a seek-scan probe (SSP) memory 100, in accordance with an embodiment of the invention. The illustrated embodiment of SSP memory 100 includes frame 102, movable platform 103, one or more coils 104, cap wafer 106, one or more recess cavities 108, magnet assembly 110 with plate 112 and one or more magnets 114 and fixed platform 116.

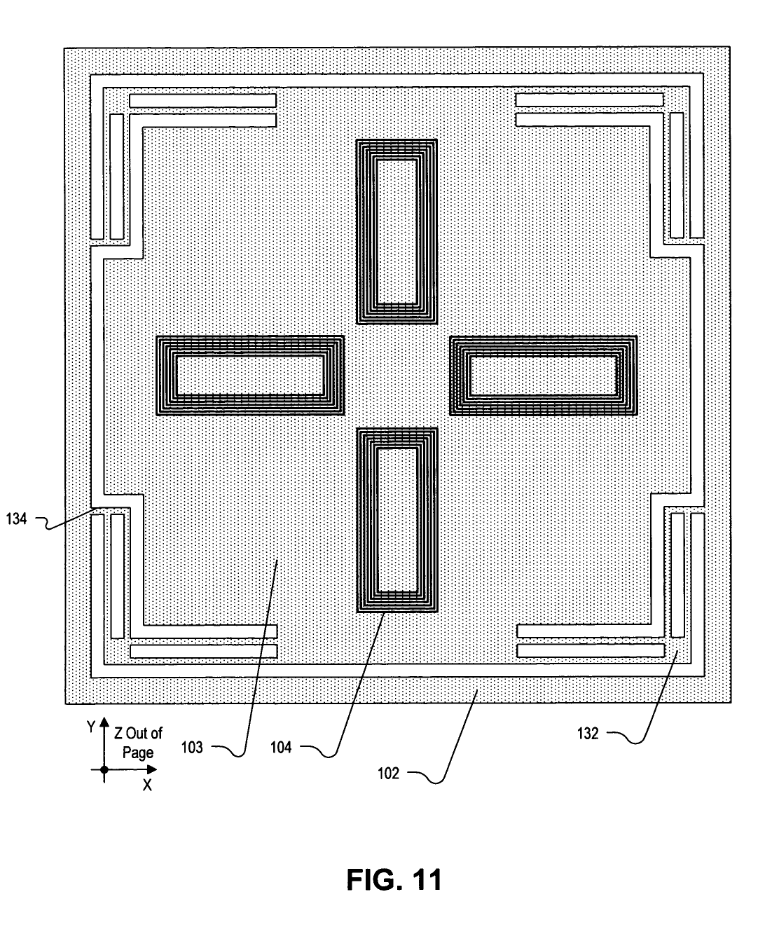

Movable platform 103 is movably coupled to frame 102 such that movable platform 103 can move relative to frame 102 in the x-y plane as indicated by the arrows in FIG. 1A. FIG. 11 is a top plan view of frame 102 with movable platform 103, in accordance with an embodiment of the invention. In the illustrated embodiment, movable platform 103 is physically connected to frame 102 with frame connector 134 and suspension 132. Frame connector 134 and suspension 132 allow movement of the movable platform relative to frame 102 in the x-y plane as indicated by the arrows in FIG. 11.

Frame 102, movable platform 103, suspension 132 and frame connector 134 can be fabricated from any kind of substrate compatible with MEMS manufacturing requirements and whose properties are consistent with the construction of SSP memory 100. In one embodiment, frame 102, movable platform 103, suspension 132, and frame connector 134 can be fabricated from a substrate of one or more of the various forms of silicon, such as polysilicon, single-crystal silicon, and the like. In other embodiments, the substrate can be made of different materials and, in still other embodiments, the substrate can be a composite made up of combinations of materials or layers of various materials.

FIG. 1B illustrates a sectional view of a portion of SSP memory 100. In the illustrated embodiment, movable platform 103 includes a layer of storage media 140 deposited on a surface of movable platform 103 that faces fixed platform 116. The storage media includes a plurality of individually addressable memory cells to which information can be written or read to by probe tip 142. In one embodiment, storage media 140 can be a chalcogenide material in which a temperature change induced in the material by current passed through it cases a small region in the material to change from a first phase with a given electrical conductivity to a second phase with a different conductivity. The resulting small region with a different electrical conductivity then represents a data bit. In another embodiment, storage media 140 can be a ferroelectric material wherein the polarizations of a small region of the material changes in response to an electric field. In still another embodiment, storage media 140 can be a polymer material with a relatively low melting point, such that when a probe tip is pressed against the material and a current is passed through it, a hole is melted in the polymer. The hole then represents a data bit.

Fixed platform 116 is coupled to frame 102 and can be fabricated from any kind of substrate compatible with MEMS manufacturing requirements and whose properties are consistent with the construction of SSP memory 100. In one embodiment, fixed platform 116 can be fabricated from a substrate of one or more of the various forms of silicon, such as polysilicon, single-crystal silicon, and the like. In other embodiments, the substrate can be made of different materials and, in still other embodiments, the substrate can be a composite made up of combinations of materials or layers of different materials.

In the illustrated embodiment, fixed platform 116 includes one or more probe tips 142 to read and write data from storage media 140 deposited on movable platform 103. In another embodiment, fixed platform 116 includes a layer of storage media and movable platform 103 includes the probe tips to read and write to/from the storage media. In still another embodiment, both movable platform 103 and fixed platform 116 include a combination of storage media and probe tips.

Referring now to both FIGS. 1A and 1B, the relative motion of movable platform 103 is driven by electromagnetic MEMS components such as an electromagnetic actuator to allow an individual probe tip 142 to access multiple memory cells. The electromagnetic actuator of SSP memory 100 includes one or more electrically conductive coils 104 and one or more magnets 114. Coils 104 are energized by passing an electrical current through them. When an energized coil 104 is subject to a magnetic field created by magnets 114 forces such as a Lorentz force are translated into physical movement of movable platform 103. By varying the current through coil 104 the position of movable platform 103 in the x-y plane can be altered, thereby allowing for selective alignment of a probe tip with various memory cells on media 140.

In one embodiment, coils 104 are fabricated on movable platform 103 and arranged as a plurality of concentric rectangles, although other arrangements can be utilized to induce the necessary force to actuate movable platform 103. In addition, although the illustrated embodiment of FIGS. 1A and 11 show four coils 104, any number of coils, including one or more may be fabricated on movable platform 103.

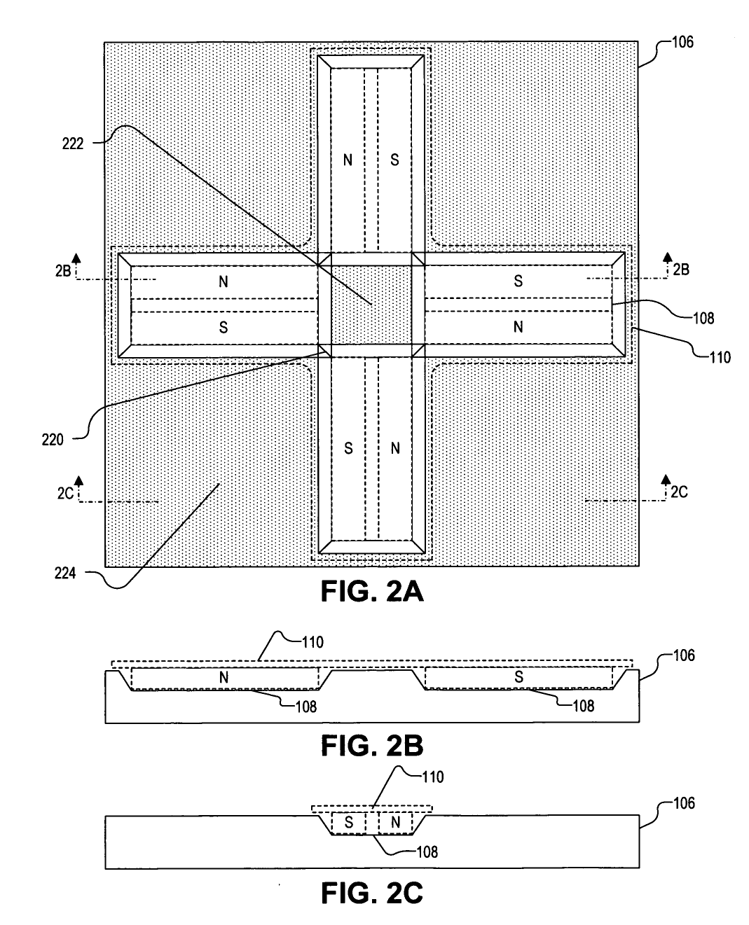

The illustrated embodiment of SSP memory 100 includes cap wafer 106 coupled to frame 102. FIGS. 2A-2C illustrate cap wafer 106 in more detail. Cap wafer 106 can be fabricated from any kind of substrate compatible with MEMS manufacturing requirements and whose properties are consistent with the construction of SSP memory 100. In one embodiment, cap wafer 106 can be fabricated from a substrate of one or more of the various forms of silicon, such as polysilicon, single-crystal silicon (with a 100 crystal orientation, in one embodiment), and the like. In other embodiments, the substrate can be made of different materials and, in still other embodiments, the substrate can be a composite made up of combinations of materials or layers of different materials.

Cap wafer 106 includes one or more recess cavities 108 etched into a top surface of cap wafer 106 to receive one or more magnets 114 of magnet assembly 110. For example, recess cavities 108 can be patterned on the surface of cap wafer 106 using photolithographic techniques and etched into the surface of cap wafer 106 by way of a wet etching technique such as potassium hydroxide (KOH) etching. Wet etching recess cavities 108, results in sloped side walls of cavities 108 which allows for a wider top window of cavities 108.

During operation of the electromagnetic actuator (i.e., magnet 114 and coil 104) a magnetic force may be exerted on cap wafer 106, that causes deflection in the direction of the z-axis. Thus, in some embodiments cap wafer 106 is fabricated to substantially maintain its structural integrity and reduce this deflection. In the illustrated embodiment, cap wafer 106 includes a bridge 220 for structurally connecting an inner portion 222 of cap wafer 106 with an outer portion 224. By way of example, bridge 220 includes un-etched portions of the substrate from which cap wafer 106 is fabricated.

The precise nature of known photolithographic patterning and etching techniques allows the creation of recess cavities 108 in locations such that magnets 114 can be passively yet very accurately aligned with coils 104. Passive alignment of magnets 114 can reduce manufacturing costs and allow for high volume manufacturing (HVM) of SSP memory 100. In one embodiment, cavities 108 are etched into cap wafer 106 at locations such that magnets 114 are laterally aligned in the x-y plane with coils 104 on movable platform 103. In one example, cavities 108 are etched such that a center of cavity 108 is aligned with a center of coil 104. In another example, cavities 108 are etched such that an edge of cavity 108 is laterally aligned in the x-y plane with an edge of coil 104. In still another example, cavities 108 are etched such that the center of cavity 108 is a fixed distance from a reference point on cap wafer 106.

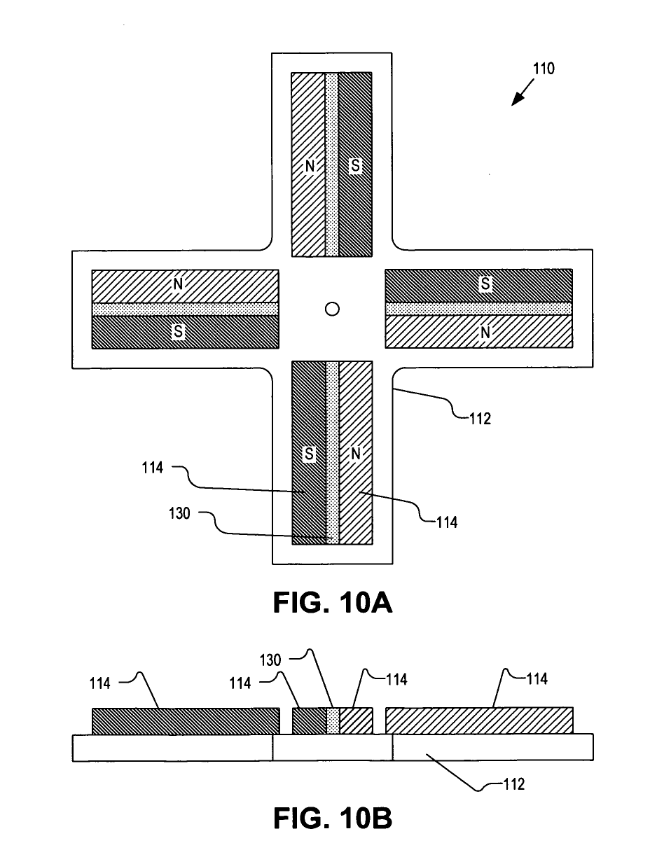

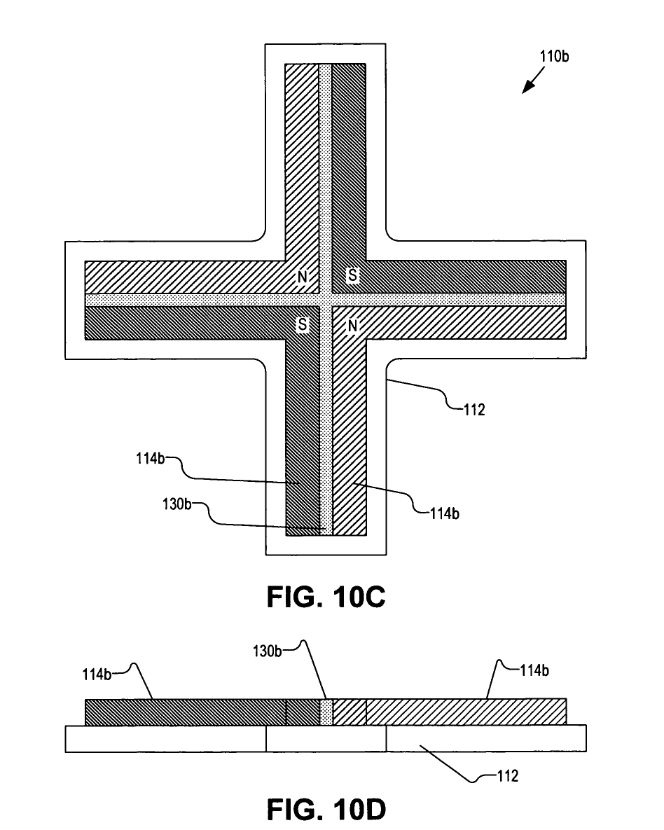

FIGS. 2A-2C illustrate the mating of magnets 114 of magnet assembly 110 with recess cavities 108. A magnet assembly 110 is shown in more detail in FIGS. 10A and 10B. The illustrated embodiment of magnet assembly 110 includes a plate 112 to which a plurality of magnets 114 are secured. In one example, plate 112 may be steel. In other examples, plate 112 may be made from any rigid material suitable for construction of SSP memory 100.

In the illustrated embodiment, magnets 114 are single-pole magnets. By way of example, single-pole magnets are glued to plate 112 with a north-pole magnet adjacent to a south-pole magnet on each leg of plate 112. Although FIGS. 10A and 10B illustrate four north-pole magnets and four south-pole magnets, any number of single or double pole magnets, including one or more, may be utilized to generate the magnetic field necessary for actuation of movable platform 103.

Magnet assembly 110 may also include an optional neutral material 130 disposed between magnets 114. By way of example, neutral material 130 may be the same material as magnets 114, but not magnetized.

Referring now back to FIGS. 2A-2C, magnet assembly 110 is coupled to cap wafer 106. In one embodiment, magnet assembly 110 is affixed to cap wafer 106 by gluing plate 112 to cap wafer 106 at the center portion 222 or at the outer portion 224. By way of example, plate 112 can be glued to cap wafer 106 with a silicon rubber or with any suitable epoxy.

In some embodiments, during operation, feedback may be necessary indicating the precise location of movable platform 103. To accommodate this, in one embodiment, location sensors 138 can be fabricated on a bottom surface of cap wafer 106 facing movable platform 103. In addition, in one embodiment, a recess 136 can be fabricated on the bottom surface of cap wafer 106 facing movable platform 103 to give clearance for movable platform 103 to move freely in the x-y plane without substantial contact between movable platform 103 and cap wafer 106.

As is shown in FIG. 1A, an optional bottom magnet assembly 110 may be included with SSP memory 100. If utilized, fixed platform 116 can include one or more recess cavities on a bottom surface of fixed platform 116 to receive magnets 114 included in magnet assembly 110. Alternatively, magnets 114 can be affixed to the bottom surface of fixed platform 116 without any recess cavities formed thereon.

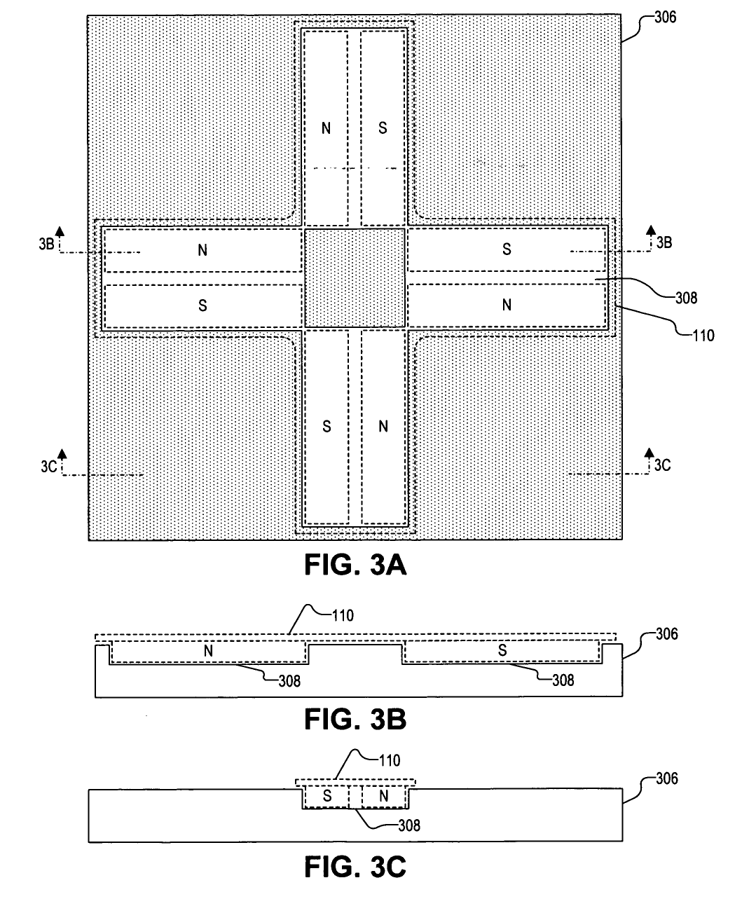

FIGS. 3A-3C illustrate an alternative cap wafer 306 with recess cavities 308. Recess cavities 308 are etched into a top surface of cap wafer 306 to receive one or more magnets 114 of magnet assembly 110. For example, recess cavities 308 can be etched into the surface of cap wafer 306 by way of a deep reactive ion etching (DRIE) technique. Using DRIE techniques results in recess cavities 308 having substantially vertical walls. The vertical walls allows for even more accurate passive alignment of magnets 114 within recess cavities 308. In one embodiment, cavities 308 are etched into cap wafer 306 at locations such that magnets 114 are laterally aligned in the x-y plane with coils 104 on movable platform 103. In one example, cavities 308 are etched such that a center of cavity 308 is aligned with a center of coil 104. In another example, cavities 308 are etched such that an edge of cavity 308 is laterally aligned in the x-y plane with an edge of coil 104. In still another example, cavities 308 are etched such that the center of cavity 308 is a fixed distance from a reference point on cap wafer 306.

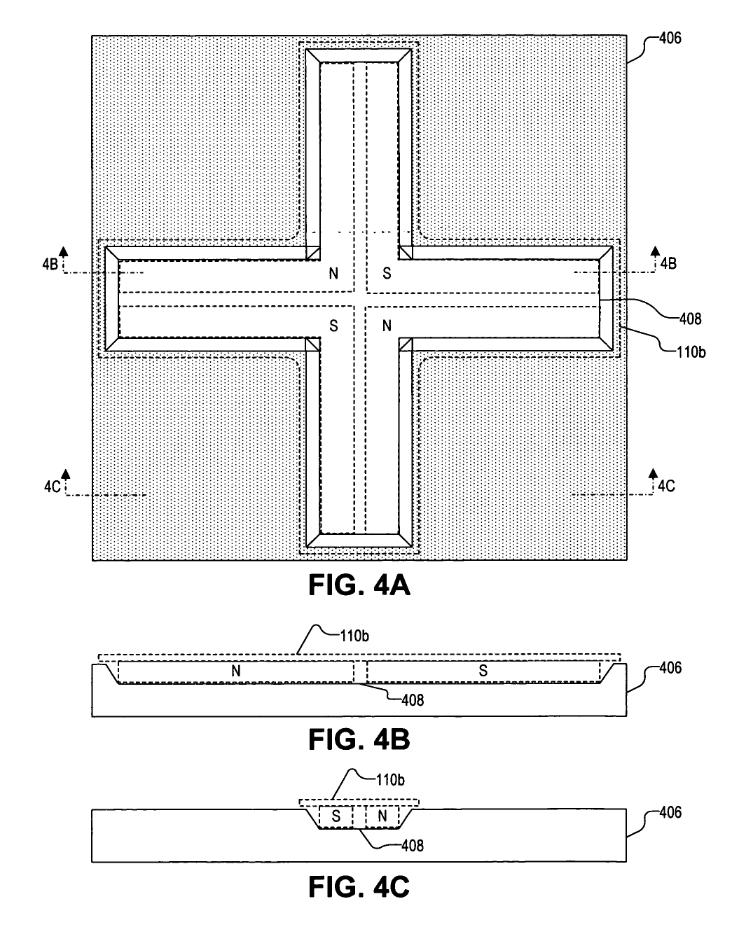

FIGS. 4A-4C illustrate an alternative cap wafer 406 with a single recess cavity 408. Recess cavity 408 is etched into a top surface of cap wafer 406 to receive one or more magnets 114b of magnet assembly 10b. For example, recess cavity 408 can be etched into the surface of cap wafer 406 by way of a wet etching technique such as potassium hydroxide (KOH) etching. Wet etching recess cavity 408 results in sloped side walls of cavity 408 which allows for a wider top window of cavity 408.

The precise nature of known photolithographic patterning and etching techniques allows the creation of a recess cavity 408 in a location such that magnets 114b can be passively yet accurately aligned with coils 104. Passive alignment of magnets 114b can reduce manufacturing costs and allow for high volume manufacturing (HVM) of SSP memory 100. In one embodiment, cavity 408 is etched into cap wafer 406 at a location such that magnets 114b are laterally aligned in the x-y plane with coils 104 on movable platform 103. In one example, cavity 408 is etched such that a center of cavity 408 is aligned with a center of movable platform 103. In another example, cavity 408 is etched such that an edge of cavity 408 is laterally aligned in the x-y plane with an edge of coil 104. In still another example, cavity 408 is etched such that the center of cavity 408 is a fixed distance from a reference point on cap wafer 406.

FIGS. 4A-4C illustrate the mating of magnets 114b with recess cavity 408. A magnet assembly 10b is shown in more detail in FIGS. 10C and 10D. The illustrated embodiment of magnet assembly 10b includes a plate 112 to which a plurality of magnets 114b are secured. In one example, plate 112 may be steel. In other examples, plate 112 may be made from any rigid material suitable for construction of SSP memory 100.

In the illustrated embodiment, magnets 114b are single-pole magnets. By way of example, single-pole magnets are glued to plate 112 with a north-pole magnet adjacent to a south-pole magnet on each leg of plate 112. Although FIGS. 10C and 10D illustrate two “L-shaped” north-pole magnets and two “L-shaped” south-pole magnets, any number of single or double pole magnets, including one or more, of any suitable shape, may be utilized to generate the magnetic field necessary for actuation of movable platform 103.

Magnet assembly 110b may also include an optional neutral material 130b disposed between magnets 114b. By way of example, neutral material 130b may be the same material as magnets 114b, but not magnetized.

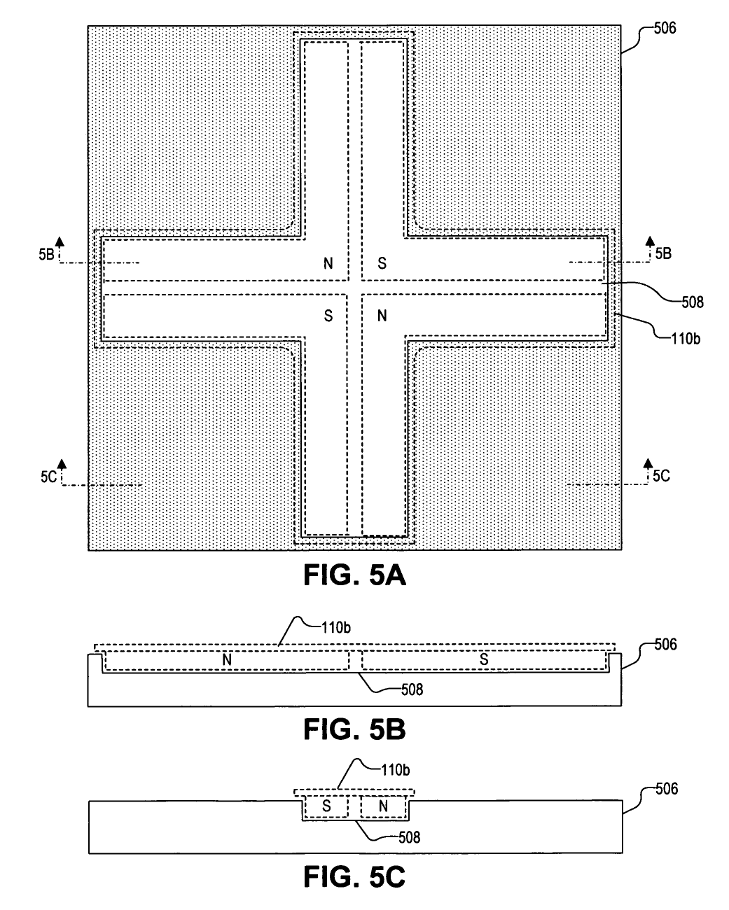

FIGS. 5A-5C illustrate an alternative cap wafer 506 with a single recess cavity 508. Recess cavity 508 is etched into a top surface of cap wafer 506 to receive one or more magnets 114b of magnet assembly 10b. For example, recess cavity 508 can be etched into the surface of cap wafer 506 by way of a deep reactive ion etching (DRIE) technique. Using DRIE techniques results in a recess cavity 508 having substantially vertical walls. The vertical walls allows for even more accurate passive alignment of magnets 114b within recess cavity 508. In one embodiment, cavity 508 is etched into cap wafer 506 at locations such that magnets 114b are laterally aligned in the x-y plane with coils 104 on movable platform 103. In one example, cavity 508 is etched such that a center of cavity 508 is aligned with a center of movable platform 103. In another example, cavity 508 is etched such that an edge of cavity 508 is laterally aligned in the x-y plane with an edge of coil 104. In still another example, cavity 508 is etched such that the center of cavity 508 is a fixed distance from a reference point on cap wafer 506.

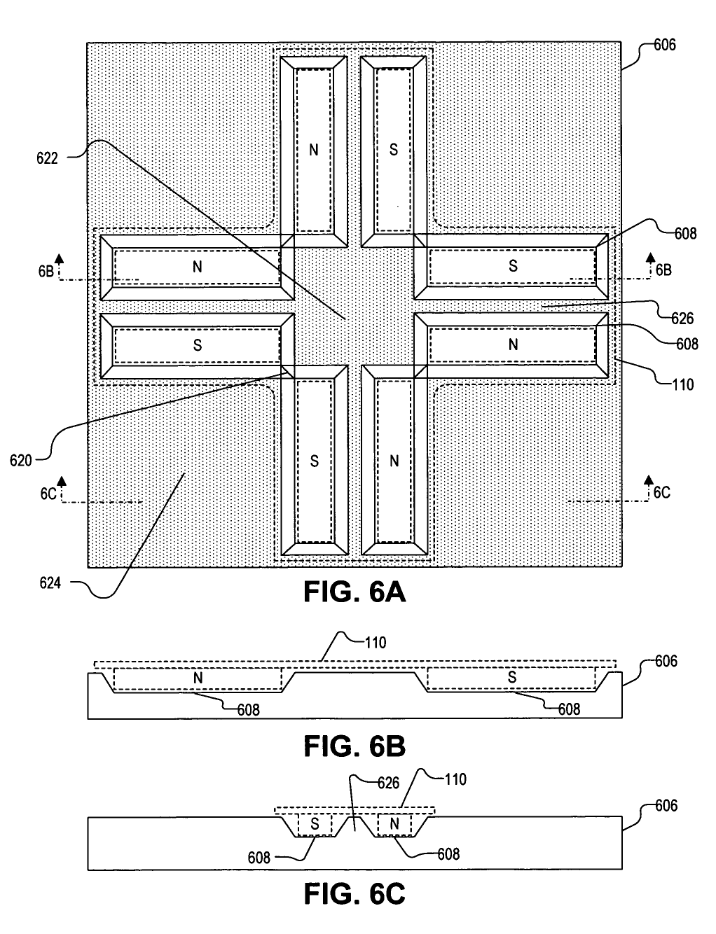

FIGS. 6A-6C illustrate an alternative cap wafer 606 with recess cavities 608. Recess cavities 608 are etched into a top surface of cap wafer 606 to receive one or more magnets 114 of magnet assembly 110. For example, recess cavities 608 can be etched into the surface of cap wafer 606 by way of a wet etching technique such as potassium hydroxide (KOH) etching. Wet etching recess cavities 608 results in sloped side walls of cavities 608 which allows for a wider top window of cavities 608.

The precise nature of known photolithographic patterning and etching techniques allows the creation of recess cavities 608 in locations such that magnets 114 can be passively yet accurately aligned with coils 104. Passive alignment of magnets 114 can reduce manufacturing costs and allow for high volume manufacturing (HVM) of SSP memory 100. In one embodiment, cavities 608 are etched into cap wafer 606 at locations such that magnets 114 are laterally aligned in the x-y plane with coils 104 on movable platform 103. In one example, cavities 608 are etched such that a center of cavity 608 is aligned with a center of coil 604. In another example, cavities 608 are etched such that an edge of cavity 608 is laterally aligned in the x-y plane with an edge of coil 104. In still another example, cavities 608 are etched such that the center of cavity 608 is a fixed distance from a reference point on cap wafer 606.

In some embodiments cap wafer 606 is fabricated to substantially maintain its structural integrity and reduce deflection of cap wafer 606 caused by the electromagnetic actuator. In the illustrated embodiment, cap wafer 606 includes a bridge 620 for structurally connecting an inner portion 622 of cap wafer 606 with an outer portion 624. By way of example, bridge 620 includes un-etched portions of the substrate from which cap wafer 606 is fabricated.

The illustrated embodiment of cap wafer 606 further includes one or more dividers 626 fabricated between recess cavities 608. Dividers 626 allow for further precision passive alignment of magnets 114 of magnet assembly 110. In addition, dividers 626 further strengthen cap wafer 606 to reduce deflection of cap wafer 606. In one embodiment, dividers 626 are fabricated in cap wafer 606 to separate a north-pole magnet 114 from a south-pole magnet 114. By way of example, dividers 626 include un-etched portions of the substrate from which cap wafer 606 is fabricated.

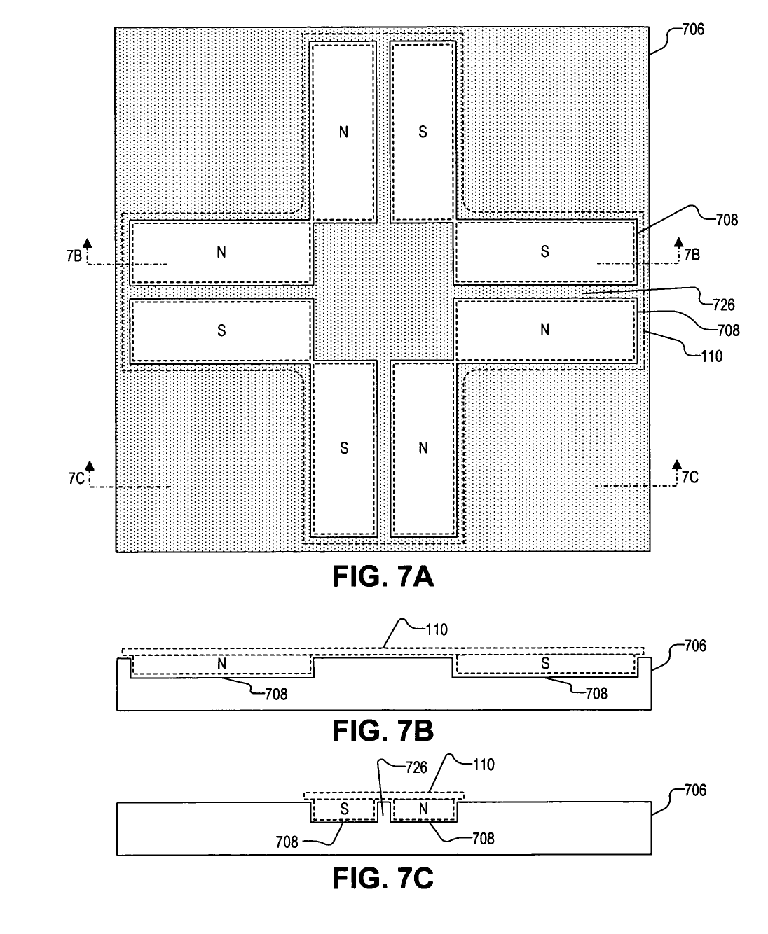

FIGS. 7A-7C illustrate an alternative cap wafer 706 with recess cavities 708. Recess cavities 708 are etched into a top surface of cap wafer 706 to receive one or more magnets 114 of magnet assembly 110. For example, recess cavities 708 can be etched into the surface of cap wafer 706 by way of a deep reactive ion etching (DRIE) technique. Using DRIE techniques results in recess cavities 708 having substantially vertical walls. The vertical walls allows for even more accurate passive alignment of magnets 114 within recess cavity 708. In one embodiment, cavities 708 are etched into cap wafer 706 at locations such that magnets 114 are laterally aligned in the x-y plane with coils 104 on movable platform 103. In one example, cavities 708 are etched such that a center of cavity 708 is aligned with a center of coil 104. In another example, cavities 708 are etched such that an edge of cavity 708 is laterally aligned in the x-y plane with an edge of coil 104. In still another example, cavity 708 is etched such that the center of cavity 708 is a fixed distance from a reference point on cap wafer 706.

The illustrated embodiment of cap wafer 706 further includes one or more dividers 726 fabricated between recess cavities 708. Dividers 726 allow for further precision passive alignment of magnets 114 of magnet assembly 110. In addition, dividers 726 strengthen cap wafer 706 to reduce deflection of cap wafer 706. In one embodiment, dividers 726 are fabricated in cap wafer 706 to separate a north-pole magnet 114 from a south-pole magnet 114. By way of example, dividers 726 include un-etched portions of the substrate from which cap wafer 706 is fabricated.

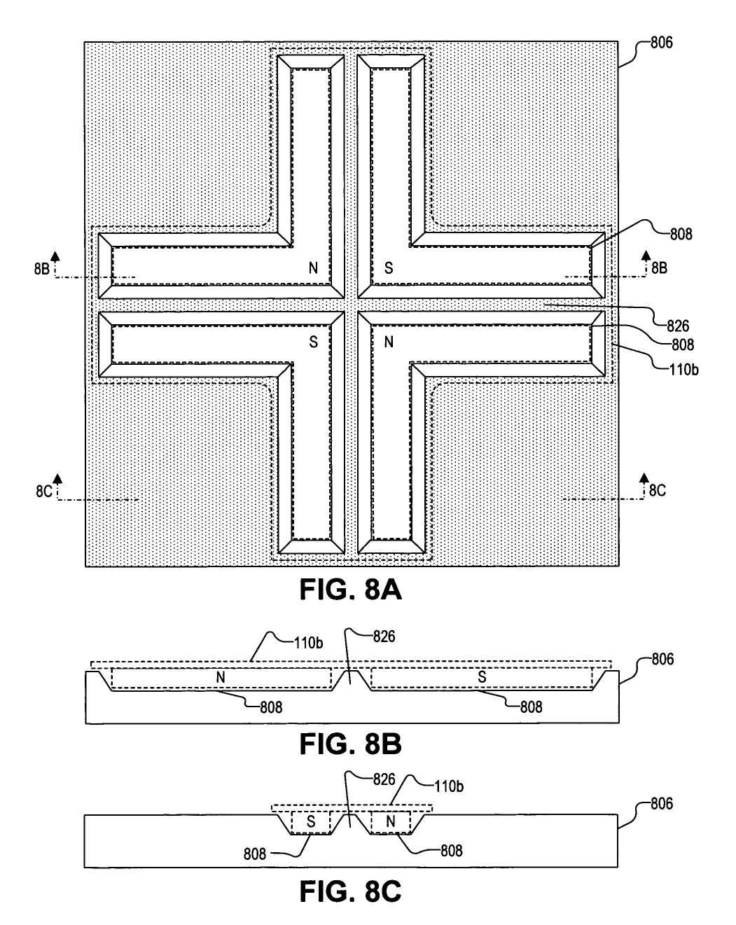

FIGS. 8A-8C illustrate an alternative cap wafer 806 with recess cavities 808. Recess cavities 808 are etched into a top surface of cap wafer 806 to receive one or more magnets 114b of magnet assembly 110b. For example, recess cavities 408 can be etched into the surface of cap wafer 806 by way of a wet etching technique such as potassium hydroxide (KOH) etching. Wet etching recess cavities 808 results in sloped side walls of cavities 808 which allows for a wider top window of cavities 808.

The precise nature of known photolithographic patterning and etching techniques allows the creation of recess cavities 808 in a location such that magnets 114b can be passively yet accurately aligned with coils 104. Passive alignment of magnets 114b can reduce manufacturing costs and allow for high volume manufacturing (HVM) of SSP memory 100. In one embodiment, cavities 808 are etched into cap wafer 806 at a location such that magnets 114b are laterally aligned in the x-y plane with coils 104 on movable platform 103. In one example, cavity 408 is etched such that a center of each leg of cavity 808 is aligned with a center of one of coils 104. In another example, cavities 808 are etched such that an edge of cavity 808 is laterally aligned in the x-y plane with an edge of coil 104. In still another example, cavities 808 are etched such that the center of cavity 808 is a fixed distance from a reference point on cap wafer 806.

The illustrated embodiment of cap wafer 806 further includes one or more dividers 826 fabricated between recess cavities 808. Dividers 826 allow for further precision passive alignment of magnets 114b of magnet assembly 10b. In addition, dividers 826 strengthen cap wafer 806 to reduce deflection of cap wafer 806. In one embodiment, dividers 826 are fabricated in cap wafer 806 to separate a north-pole magnet 114b from a south-pole magnet 114b. By way of example, dividers 826 include un-etched portions of the substrate from which cap wafer 806 is fabricated.

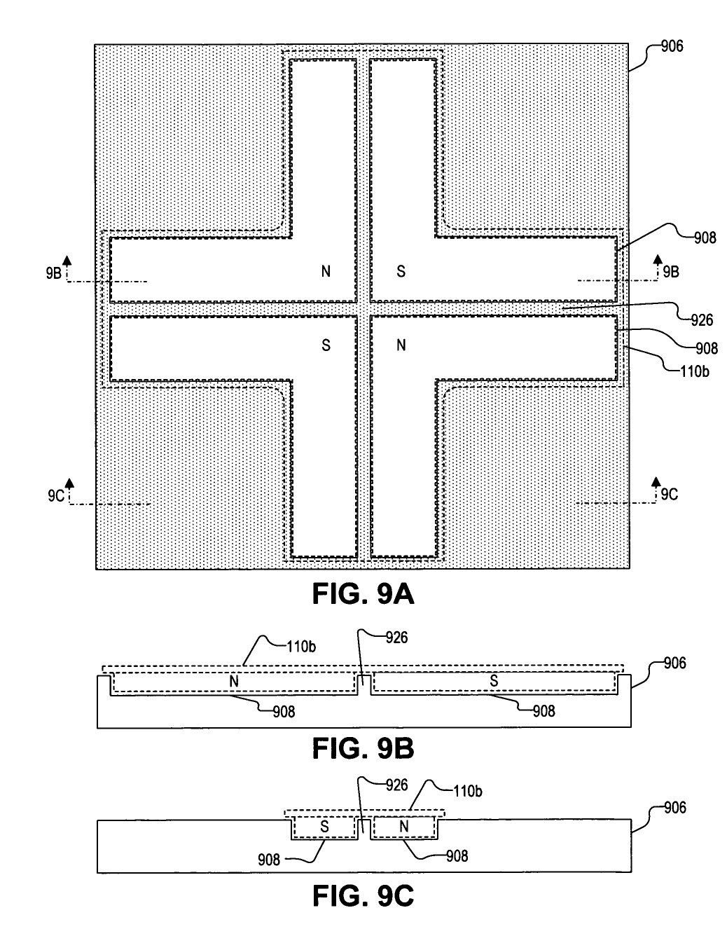

FIGS. 9A-9C illustrate an alternative cap wafer 906 with recess cavities 908. Recess cavities 908 are etched into a top surface of cap wafer 906 to receive one or more magnets 114b of magnet assembly 110b. For example, recess cavities 908 can be etched into the surface of cap wafer 906 by way of a deep reactive ion etching (DRIE) technique. Using DRIE techniques results in recess cavities 908 having substantially vertical walls. The vertical walls allows for even more accurate passive alignment of magnets 114b within recess cavity 908. In one embodiment, cavities 908 are etched into cap wafer 906 at locations such that magnets 114b are laterally aligned in the x-y plane with coils 104 on movable platform 103. In one example, cavity 908 is etched such that a center of each leg of cavity 908 is aligned with a center of one of coils 104. In another example, cavity 908 is etched such that an edge of cavity 908 is laterally aligned in the x-y plane with an edge of coil 104. In still another example, cavity 908 is etched such that the center of cavity 908 is a fixed distance from a reference point on cap wafer 906.

The illustrated embodiment of cap wafer 906 further includes one or more dividers 926 fabricated between recess cavities 908. Dividers 926 allow for further precision passive alignment of magnets 114b of magnet assembly 10b. In addition, dividers 926 strengthen cap wafer 906 to reduce deflection of cap wafer 906. In one embodiment, dividers 926 are fabricated in cap wafer 906 to separate a north-pole magnet 114b from a south-pole magnet 114b. By way of example, dividers 926 include un-etched portions of the substrate from which cap wafer 906 is fabricated.

As with cap wafer 106, any of the previously mentioned alternative cap wafers 306, 406, 506, 606, 706, 806, and 906 can be fabricated from any kind of substrate compatible with MEMS manufacturing requirements and whose properties are consistent with the construction of SSP memory 100. In one embodiment, the cap wafers can be fabricated from a substrate of one or more of the various forms of silicon, such as polysilicon, single-crystal silicon (with a 100 crystal orientation, in one embodiment), and the like. In other embodiments, the substrate can be made of different materials and, in still other embodiments, the substrate can be a composite made up of combinations of materials or layers of different materials (e.g. Si(100)).

In addition, as with cap wafer 106, cap wafers 406, 506, 606, 706, 806, and 906 can optionally include position sensors fabricated on a bottom surface of the cap wafer, facing movable platform 103, to track the precise location of movable platform 103. In one embodiment position sensors are located on movable platform 103. In addition, in one embodiment, a recess may be fabricated on the bottom surface of the cap wafer, facing movable platform 103, to give clearance for movable platform 103 to move freely in the x-y plane without substantial contact between movable platform 103 and the cap wafer.

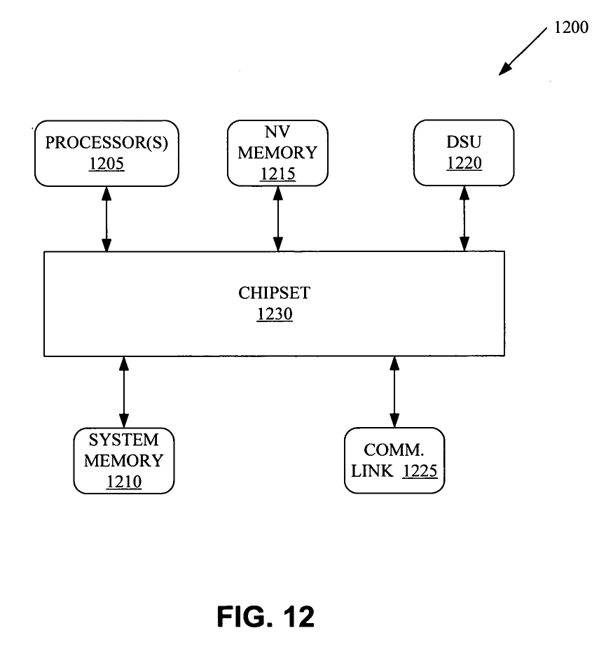

FIG. 12 is a block diagram illustrating a demonstrative processing system 1200. The illustrated embodiment of processing system 1200 includes one or more processors (or central processing units) 1205, system memory 1210, nonvolatile (NV) memory 1215, a data storage unit (DSU) 1220, a communication link 1225, and a chipset 1230. The illustrated processing system 1200 may represent a computing system including a desktop computer, a notebook computer, a workstation, a handheld computer, a server, a blade server, or the like.

The elements of processing system 1200 are interconnected as follows. Processor(s) 1205 is communicatively coupled to system memory 1210, NV memory 1215, DSU 1220, and communication link 1225, via chipset 1230 to send and to receive instructions or data thereto/therefrom. In one embodiment processor 1205 can be a traditional general-purpose microprocessor, although in other embodiments processor 1205 can be another type of processor, such as a programmable controller or an application-specific integrated circuit (ASIC).

In one embodiment, NV memory 1215 may include a seek-scan probe (SSP) memory with a cap wafer such as one or more of cap wafers 106, 306, 406, 506, 606, 706, 806, and 906.

In one embodiment, system memory 1210 includes random access memory (RAM), such as dynamic RAM (DRAM), synchronous DRAM, (SDRAM), double data rate SDRAM (DDR SDRAM) static RAM (SRAM), and the like. DSU 1220 represents any storage device for software data, applications, and/or operating systems, but will most typically be a nonvolatile storage device. DSU 1220 may optionally include one or more of an integrated drive electronic (IDE) hard disk, an enhanced IDE (EIDE) hard disk, a redundant array of independent disks (RAID), a small computer system interface (SCSI) hard disk, a serial advanced technology attachment (SATA or Serial ATA) and the like. Although DSU 1220 is illustrated as internal to processing system 1200, DSU 1220 may be externally coupled to processing system 1200. Communication link 1225 may couple processing system 1200 to a network such that processing system 1200 may communicate over the network with one or more other computers. Communication link 1225 may include a modem, an Ethernet card, a Gigabit Ethernet card, Universal Serial Bus (USB) port, a wireless network interface card, a fiber optic interface, or the like.

It should be appreciated that various other elements of processing system 1200 have been excluded from FIG. 12 and this discussion for the purpose of clarity. For example, processing system 1200 may further include a graphics card, additional DSUs, other persistent data storage devices (e.g., tape drive), and the like. Chipset 1230 may also include a system bus and various other data buses for interconnecting subcomponents, such as a memory controller hub and an input/output (I/O) controller hub, as well as, data buses (e.g., peripheral component interconnect bus) for connecting peripheral devices to chipset 1230. Moreover, processing system 1200 may operate without one or more of the elements illustrated. For example, processing system 1200 need not include DSU 1220.

In operation of system 1300, processor 1305 can both read and write data to both RAM 1310 and NV memory 1315. Through appropriate software, processor 1305 can control the reading, writing and erasure of data in NV memory 1315 by selectively changing the media property (heating phase change or electric dipole formation) in the relevant cell.

The above description of illustrated embodiments of the invention, including what is described in the abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. An apparatus comprising:
a movable platform movably coupled to a frame;
an electrically conductive coil coupled to the movable platform; and
a cap wafer coupled to the frame and including therein a recess cavity configured to receive a magnet and positioned such that the electrically conductive coil will be subject to a magnetic field of the magnet when the magnet is placed in the recess cavity.

2. The apparatus of claim 1, wherein the recess cavity is configured to passively align the magnet with the coil.

3. The apparatus of claim 1, wherein the cap wafer further comprises a plurality of recess cavities configured to receive a plurality of magnets of a magnet assembly.

4. The apparatus of claim 3, wherein the magnet assembly further comprises a plurality of single-pole magnets of a first polarity and a plurality of single-pole magnets of a second polarity.

5. The apparatus of claim 4, wherein the cap wafer further comprises at least one divider to separate single-pole magnets of the first polarity from single-pole magnets of the second polarity.

6. The apparatus of claim 3, wherein the cap wafer further comprises a bridge disposed between each of the plurality of recess cavities to provide structural support to the cap wafer.

7. The apparatus of claim 1, wherein the movable platform comprises a media layer including media, the apparatus further comprising a fixed platform coupled to the frame, the fixed platform including a probe tip extending therefrom, the probe tip arranged so that the media is accessible to the probe tip.

8. A system comprising:
a processor;
a random access memory (“RAM”) coupled to the processor; and
a nonvolatile (“NV”) memory coupled to the processor, the NV memory comprising:
a movable platform movably coupled to a frame;
an electrically conductive coil coupled to the movable platform; and
a cap wafer coupled to the frame and including therein a recess cavity configured to receive a magnet and positioned such that the electrically conductive coil will be subject to the magnetic field of the magnet when the magnet is placed in the recess cavity.

9. The system of claim 8, wherein the recess cavity is configured to passively align the magnet with the coil.

10. The system of claim 8, wherein the cap wafer further comprises a plurality of recess cavities configured to receive a plurality of magnets of a magnet assembly.

11. The system of claim 10, wherein the magnet assembly further comprises a plurality of single-pole magnets of a first polarity and a plurality of single-pole magnets of a second polarity.

12. The system of claim 11, wherein the cap wafer further comprises at least one divider to separate single-pole magnets of the first polarity from single-pole magnets of the second polarity.

13. The system of claim 10, wherein the cap wafer further comprises a bridge disposed between each of the plurality of recess cavities to provide structural support to the cap wafer.

14. An apparatus comprising:
a movable platform movably coupled to a frame;
an electrically conductive coil coupled to the movable platform; and p1 a cap wafer coupled to the frame and including therein means to receive and self-align a magnet with the electrically conductive coil such that the electrically conductive coil is subject to the magnetic field of the magnet.

15. The apparatus of claim 14, further comprising a magnet assembly coupled to the cap wafer, the magnet assembly including a plurality of magnets for mating with the means to receive and self-align the magnet.

16. The apparatus of claim 15, wherein the cap wafer further comprises a divider means for separating the plurality of magnets from one another.

17. The apparatus of claim 16, wherein the magnet assembly further includes a plurality of north-pole magnets, a plurality of south-pole magnets, and a plurality of neutral elements disposed between north and south-pole magnets.

18. The apparatus of claim 14, wherein the cap wafer further comprises a bridge means for structurally connecting a center portion of the cap wafer to an outer portion of the cap wafer.

19. The apparatus of claim 14, wherein the movable platform comprises a media layer including media, the apparatus further comprising a fixed platform coupled to the frame, the fixed platform including a probe tip extending therefrom, the probe tip arranged so that the media is accessible to the probe tip.

20. A process comprising:
patterning and etching a recess cavity in a cap wafer, the recess cavity being configured to receive a magnet; and
coupling the cap wafer to a frame, the frame having a movable platform with an electrically conductive coil coupled thereto, wherein the position of the recess cavity relative to the electrically conductive coil is such that the electrically conductive coil will be subject to a magnetic field when a magnet is placed in the recess cavity.

21. The process of claim 20, further comprising inserting a magnet into the recess cavity.

22. The process of claim 21, wherein the recess cavity passively aligns the magnet with the electrically conductive coil.

23. The process of claim 21, further comprising fabricating a layer of storage media on a surface of the movable platform opposite where the electrically conductive coil is coupled.

24. The process of claim 23, further comprising:
fabricating a fixed platform having a probe tip extending therefrom; and
coupling the fixed platform to the frame on a side of the frame opposite where the cap wafer is coupled such that media storage is accessible to the probe tip.
